(19) United States
(12) Patent Application Publication
(10) Pub. No.: US 2012/0162031 A1
(43) Pub. Date: Jun. 28, 2012

(54) METHOD FOR PREDICTING PHASE PATTERN USING MAGNITUDE PATTERN IN NEAR-FIELD OR FRESNEL FIELD

(75) Inventors: Soon-Soo Oh, Daejeon (KR); Seong-Min Kim, Daejeon (KR); Young-Hwan Lee, Daejeon (KR)

(73) Assignee: ELECTRONICS AND TELECOMMUNICATIONS RESEARCH INSTITUTE, Daejeon (KR)

(21) Appl. No.: 13/334,530

(22) Filed: Dec. 22, 2011

(30) Foreign Application Priority Data
Dec. 22, 2010 (KR) 10-2010-0132360
Oct. 26, 2011 (KR) 10-2011-0110061

(51) Int. Cl. G01R 29/10

(52) U.S. Cl. 343/703

(57) ABSTRACT

Disclosed is a method for predicting a phase pattern using a magnitude pattern in near-field or Fresnel field formed by antenna radiation, including: determining a first parameter group including a first actual distance between a source antenna and a probe and the magnitude pattern at the first distance; assuming a second parameter group including a second distance that is an effective distance between the source antenna and the probe, a current magnitude distribution of the source antenna and a current phase distribution of the source antenna, based on the first parameter group; calculating the magnitude pattern at the first distance based on the second parameter group; and determining the phase pattern at the first distance when the magnitude pattern at the calculated first distance matches with the magnitude pattern at the first distance included in the first parameter group by the comparison therebetween.

### CROSS-REFERENCES TO RELATED APPLICATIONS

The present application claims priority of Korean Patent Application Nos. 10-2010-0132360 and 10-2011-0110061, filed on Dec. 22, 2010 and Oct. 26, 2011, respectively, which are incorporated herein by reference in their entireties

### BACKGROUND OF THE INVENTION

1. Field of the Invention

Exemplary embodiments of the present invention relate to a method for predicting a phase pattern using a magnitude pattern in near-field or Fresnel field, and more particularly, to a method for predicting a phase pattern from a magnitude pattern in near-field or Fresnel field depending on a distance of a signal radiated from an antenna.

2. Description of Related Art

Generally, as a method for measuring radiation characteristics of an antenna, there may be a far-field measuring method, a near-field measuring method, a Fresnel field measuring method, or the like.

First, the far-field measuring method can acquire a desired value by one-time radiation from an antenna, but needs to space a distance between a source antenna and a test antenna so as to acquire a far-field radiation pattern in response to far-field conditions. Therefore, the far-field measuring method needs to make a size of a chamber large.

For example, L is a length of an aperture of an antenna for measurement, λ is an L wavelength of an operating frequency, wherein a far-field radiation pattern minimum spaced distance of an antenna of 20λ (L=20λ) operated at a frequency 10 GHz is 24 m. Therefore, the far-field measuring method cannot be performed in an anechoic chamber having a smaller value than the aforementioned value.

As an alternative method, the near-field measuring method and the Fresnel field measuring method perform a measurement at a closer distance, as compared with the far-field measuring method and therefore, may be applied even to a small chamber. However, the near-field measuring method and the Fresnel field measuring method need to acquire data at a plurality of points and therefore, has a measurement time longer than the far-field measuring method.

In particular, the near-field measuring method needs a power value at a point having an interval smaller than a half wavelength and therefore, consumes a long time to acquire all the data. The Fresnel field measuring method has the smaller number of data acquisition points than the far-field measuring method and therefore, has a short measurement time and makes a structure of device simple.

Meanwhile, the far-field measuring method, the near-field measuring method, the Fresnel measuring method may cause problems at the time of measuring effective radiated power (ERP) for wireless devices such as base stations, relays, or the like, that are installed on the spot.

The far-field measuring method needs to space the base stations, the relays, the terminals from one another so as to satisfy the far-field conditions and therefore, is difficult to acquire accurate values due to electromagnetic waves incoming through a multipath. On the other hand, the near-field measuring method and the Fresnel field measuring method perform the data acquisition at a closer distance than the far-field measuring method and therefore, can suppress the multipath effect. However, the near-field measuring method and the Fresnel field measuring method have a problem in that power calculated by the measurement has only a magnitude value. Therefore, there is a need to recover a phase value from the magnitude value in order to being converted into the far-field value.

In the related art, a method for recovering a phase value from a magnitude value of two planes has been mainly used. However, the situation in which the measurement cannot be performed at two points due to obstacles at the time of performing the measurement in the field may be frequently caused. Further, it is possible to shorten the overall calculation time according to how accurately the initially set phase value is predicted, even though the values of two planes are used.

### SUMMARY OF THE INVENTION

An embodiment of the present invention is directed to provide a method for predicting a phase pattern from a magnitude pattern in near-field or Fresnel field according to a distance of a signal radiated from an antenna.

The objects of the present invention are not limited to the above-mentioned objects and therefore, other objects and advantages of the present invention that are not mentioned may be understood by the following description and will be more obviously understood by exemplary embodiments of the present invention. In addition, it can be easily appreciated that objects and advantages of the present invention may be implemented by means and a combination thereof described in claims.

In accordance with an embodiment of the present invention, a method for predicting a phase pattern using a magnitude pattern in near-field or Fresnel field formed by antenna radiation includes: determining a first parameter group including a first actual distance between a source antenna and a probe and the magnitude pattern at the first distance; assuming a second parameter group including a second distance that is an effective distance between the source antenna and the probe, a current magnitude distribution of the source antenna and a current phase distribution of the source antenna, based on the first parameter group; calculating the magnitude pattern at the first distance based on the second parameter group; and determining the phase pattern at the first distance when the magnitude pattern at the calculated first distance matches with the magnitude pattern at the first distance included in the first parameter group by the comparison therebetween.

### BRIEF DESCRIPTION OF THE DRAWINGS

FIGS. 1A and 1B are diagrams for describing a far-field measuring method using a magnitude pattern in near-field or Fresnel field in accordance with an embodiment of the present invention.

FIG. 2 is an explanation diagram of an angle coordinate system of an antenna for describing the embodiment of the present invention.

FIG. 3 is a flow chart illustrating a method for predicting a phase pattern in near-field or Fresnel field according to the embodiment of the present invention.

FIG. 4 is a graph illustrating comparison results of a phase pattern of far-field and a phase pattern of far-field in accordance with the embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

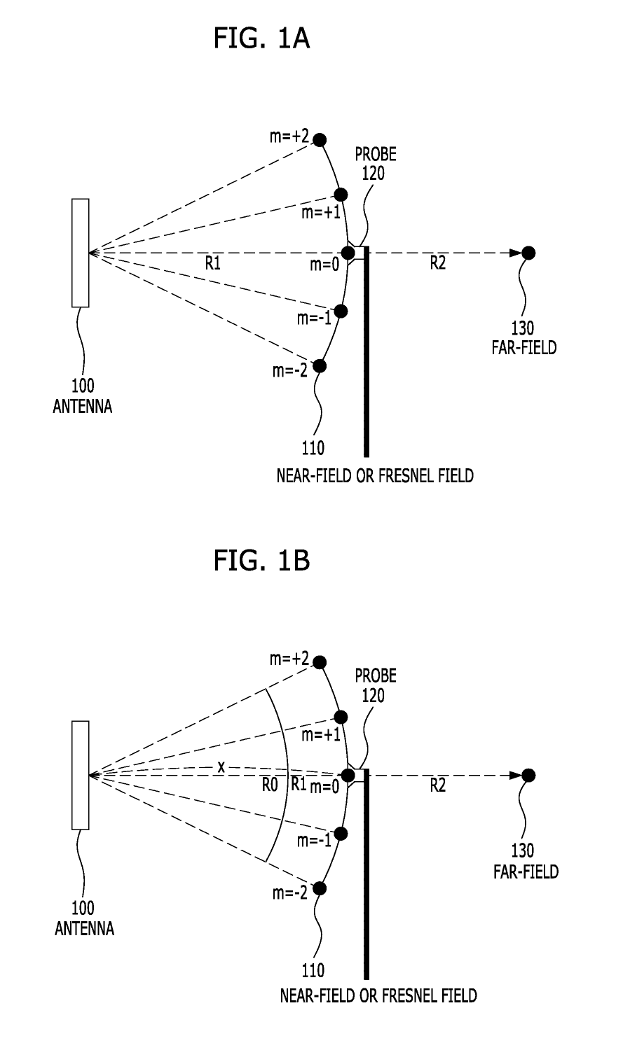

FIGS. 1A and 1B illustrate a far-field measuring method using a magnitude pattern in near-field or Fresnel field in accordance with an embodiment of the present invention.

Prior to describing FIGS. 1A and 1B, a plane forming the near-field or the Fresnel field is not limited to a spherical surface and therefore, may be formed to have a flat surface or a cylindrical surface. Data on the flat surface or the cylindrical surface are transformed into data on the spherical surface by an inter-coordinate transform or data on the flat surface or the cylindrical surface are transformed into data on the spherical surface by the correction of values.

As illustrated in FIGS. 1A and 1B, a system for measuring far-field using a magnitude pattern in near-field or Fresnel field is configured to include an antenna 100 that outputs a transmit RF signal and a probe 120 acquiring a wave radiated from the antenna 100.

The antenna 100, which is an antenna of wireless devices such as a base station antenna, outputs the RF signal generated through a network analyzer (NA) transmitted through an RF cable in near-field or the Fresnel field 110. Further, a wavelength radiated from the source antenna 100 is acquired through a probe 120 mounted at a point spaced by a distance R1. A region from the source antenna 100 to the probe 120 has only a magnitude value in the near-field or the Fresnel field.

The embodiment of the present invention predicts the phase pattern through the magnitude pattern in the near-field or the Fresnel field and then, converts the predicted phase pattern into a far-field value at a point spaced by a distance R2 from the source antenna 100 by the following Equations.

Similar to FIG. 1A, FIG. 1B is to describe a method for converting the magnitude pattern of the near-field or the Fresnel field 110 into the far-field value 110. However, the near-field or the Fresnel field 110 has the magnitude pattern on two planes of a distance R0 and an actual distance R1 and predicts the phase value through an exchange between values on the two planes, or the like. In this case, when an initial phase value is set, the overall calculation time can be shortened using the embodiment of the present invention.

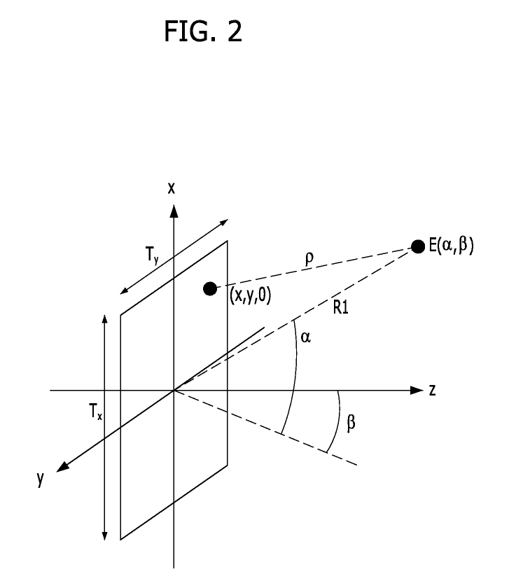

FIG. 2 is a diagram of an angle coordinate system of the antenna for describing the embodiment of the present invention.

As illustrated in FIG. 2, an original point of the coordinate side represents a central coordinate of an aperture of the antenna 100, Tx represents an x-axis length of the aperture of the antenna 100, Ty represents a y-axis length of the aperture of the antenna 100, α represents a vertical angle from a y-z plane, and β represents a vertical angle of an x-z plane.

In addition, the actual distance R1 represents a distance from the central coordinate of the aperture of the antenna 100 to the probe 120, ρ represents a distance from a point spaced by a predetermined distance from a center on the aperture of the antenna 100 to the probe 120, and ER1 (α, β) represents the values of the near field and the Fresnel field 110 to ρ and the actual distance R1.

Hereinafter, the method for predicting a phase pattern in the near-field or the Fresnel field 110 in accordance with the embodiment of the present invention will be described with reference to [Table 1], FIGS. 1A, 2, and 3.

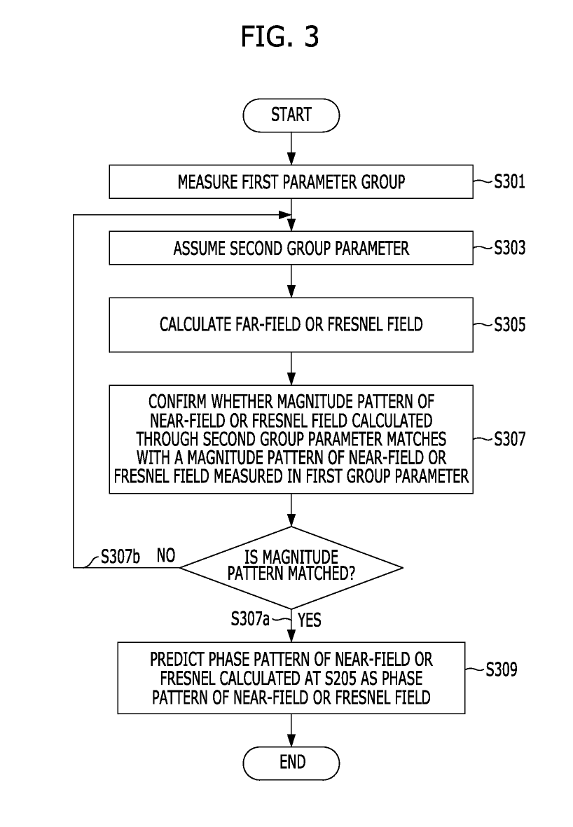

FIG. 3 is a flow chart of one embodiment of the method for predicting a phase pattern in the near-field or the Fresnel field in accordance with the embodiment of the present invention, which will be described with reference to the method for one plane.

TABLE 1

| Parameter Group | Value of parameter group |
|---|---|
| First Parameter | Frequency |
| group | Physical size (Tx, Ty) of aperture of |
| | source antenna |
| | Actual distance R1 between source Antenna |
| | and probe |
| | Magnitude pattern at actual distance R1 |
| Second Parameter | Effective size (Tx′, Ty′) of aperture of |
| group | source antenna |
| | Effective distance (R1′) between source |
| | antenna and probe |
| | Current magnitude distribution (fmx, fmy) |
| | of source antenna |
| | Current phase distribution (fpx, fpy) of |
| | source antenna |

First, as illustrated in FIG. 3, the values of the first parameter group of the antenna are determined (S301). In other words, the frequency, the physical size (Tx, Ty) of the aperture of the source antenna, the actual distance R1 between the source antenna and the probe, and the magnitude pattern at the distance R1 that are the first parameter group are determined. Here, Tx represents an x-axis length of the aperture and Ty is a y-axis length of the aperture.

Further, the second parameter group is assumed based on the first parameter group determined as described above (S303). The second parameter group includes Tx′ and Ty′ representing the effective size of the aperture of the source antenna 100, R1′ representing the effective distance from the center of the aperture of the source antenna 100 to the probe 120, fmx and fmy representing the current magnitude distribution of the source antenna 100, and fpx and fpy representing the current phase distribution of the source antenna 100. Here, Tx′ and Ty′ representing the effective size of the aperture of the source antenna 100 are set to be equal to Tx and Ty representing the physical size of the aperture of the source antenna 100 in the first parameter group. In addition, the effective distance R1′ from the center of the aperture of the source antenna 100 to the probe 120 is set to be equal to the actual distance R1 from the center of the aperture of the source antenna 100 to the probe 120 in the first parameter group. fmx and fmy that are the current magnitude distribution of the source antenna 100 each represent the x-axis current magnitude distribution and the y-axis current magnitude distribution. Further, fpx and fpy that are the current phase distribution of the source antenna 100 each represent the x-axis current phase distribution and the y-axis current phase distribution.

Further, the magnitude pattern at the actual distance R1 between the source antenna and the probe is measure using the second parameter group (S305).

First, ρ representing a distance from the point spaced from a predetermined distance from the center on the aperture of the source antenna 100 to the probe 120 is calculated. The distance value of the distance ρ may be represented by the following [Equation 1].

$$p = \sqrt{{( R 1 sin α - x )}^{2} + {( R 1 cos α sin β - γ )}^{2} + {( R 1 cos αcosβ )}^{2}} \qquad [ Equation 1 ]$$

Referring to FIG. 2, α is a vertical angle from the y-z plane and β is a vertical angle from the x-z plane.

Then, the magnitude pattern and the phase pattern are calculated by calculating the near-field or the Fresnel field 110 based on the ρ representing the distance from the point spaced by the predetermined distance from the center on the aperture of the source antenna 100 to the probe 120 and the second parameter group. The near-field or the Fresnel field 110 may be represented by the following [Equation 2].

$${E}_{R 1} ( α , β ) = \int {\int }_{s}^{ } f ( x , y ) {e}^{- i \frac{2 π}{λ} p} d x d y \qquad [ Equation 2 ]$$

Here, referring to FIG. 2, ER1 (α, β) represents electric field of the near-field or the Fresnel field 110 for the ρ and the effective actual distance R1′, α represents the angle from the y-z plane, and β represents the angle from the x-z plane. In addition, f(x,y) represents the current size and the phase distribution value of the antenna 100. In addition, the ρ represents the distance from the point spaced by the predetermined distance from the center on the aperture of the antenna to the probe 120.

Then, the above [Equation 2] may be represented by a general Formula, such as the following [Equation 3] or [Equation 4].

$$\begin{matrix}{E}_{R 1} ( α , β ) = \int {\int }_{s}^{ } f ( x , y ) {e}^{- i \frac{2 π}{λ} p} d s & [ Equation 3 ] \\ {E}_{R 1} ( α , β ) = \int {\int }_{s}^{ } f ( x , y ) \frac{( 1 + i \frac{2 π}{λ} p )}{{p}^{3}} {e}^{- i \frac{2 π}{λ} p} d s & [ Equation 4 ]\end{matrix}$$

Here, E represents the near-field or the Fresnel field 110, R1 represent the distance from the antenna to the probe, α represents the vertical angle from the y-z plane, β represents the vertical angle from the x-z plane, S represents an area of the aperture of the antenna 100, f(x,y) represents the current magnitude distribution and the current phase distribution value, and ρ represents the distance from the point spaced by the predetermined distance from the center on the aperture of the antenna 100 to the probe.

Further, it is confirmed that the magnitude pattern of the near-field or the Fresnel field 110 calculated through the second parameter group matches with the magnitude pattern measured in the first parameter group by the comparison therebetween (S307).

As the comparison result (S307), if it is determined that the magnitude pattern calculated in the first parameter group matches with the magnitude pattern measured through the second parameter group (S307a), the phase pattern of the near-field or the Fresnel field 110 calculated through the second parameter group is predicted as the phase pattern of the near-field or the Fresnel field 110 (S309).

However, if it is determined that the magnitude pattern of the first parameter group does not match with the magnitude pattern of the second parameter group (S307b), a process returns to S303. At S303, the process is performed under the re-assumption of the current magnitude distribution and the current phase distribution of the antenna 100 in the second parameter group.

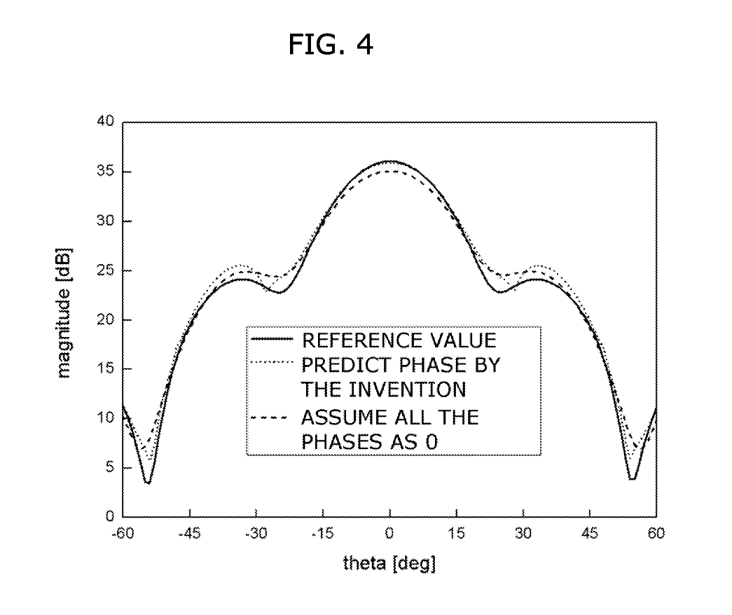

FIG. 4 is a graph illustrating comparison results of a phase pattern of far-field and a phase pattern of far-field in accordance with the embodiment of the present invention.

FIG. 4 illustrates results of comparing and analyzing of the phase pattern of the far-field (hereinafter, referred to as the ‘far-field value’) with the phase pattern of the far-field predicted from the magnitude pattern of the near-field or the Fresnel filed 110.

First, a solid line represents the accurate far-field value at the point spaced by the distance R2 from the antenna 100 and is defined by a reference value for describing FIG. 4.

A dotted line represents a value converted into the far-field value after predicting the phase pattern from the magnitude pattern of the near-field or the Fresnel field 110 acquired at the actual distance R1 using the phase prediction method proposed in the embodiment of the present invention.

A dashed line represents a value converted into the far-field value under the assumption that the phase pattern is 0.

In the case of using the phase prediction method of the embodiment of the present invention, the reference value and the far-field value at θ=0° have a small error of 0.2 dB when comparing with the reference value at θ=0°.

However, under the assumption that the phase pattern is 0, the reference value and the far-field value at θ=0° have a large error of 1.0 dB when comparing with the reference value at θ=0°.

Therefore, it can be appreciated that the method for predicting a phase from a magnitude pattern in the Fresnel field acquired at the actual distance R1 by using the method for predicting a phase proposed in the embodiment of the present invention and the method for converting the far-field value into the far-field value may have the high accuracy.

Meanwhile, the method according to the embodiment of the present invention can be prepared by a computer program. Further, a code and a code segment configuring the program may be easily inferred by a computer programmer in the corresponding field. In addition, the prepared program is stored in a computer-readable recording medium (information storage medium) and is read and executed by a computer, thereby implementing the method of the embodiment of the present invention. Further, the recording medium includes all the types of computer readable recording media.

As set forth above, the exemplary embodiments of the present invention can predict the phase pattern by measuring the magnitude pattern in the near-field and the Fresnel field according to the radiation distance of the signal radiated from the antenna, obtain the accurate far-field radiation pattern through the predicted phase pattern and the existing magnitude pattern, and acquire the effective radiated power within a short time.

While the present invention has been described with respect to the specific embodiments, it will be apparent to those skilled in the art that various changes and modifications may be made without departing from the spirit and scope of the invention as defined in the following claims.

What is claimed is:

1. A method for predicting a phase pattern using a magnitude pattern in near-field or Fresnel field formed by antenna radiation, the method including:
determining a first parameter group including a first actual distance between a source antenna and a probe and the magnitude pattern at the first distance;
assuming a second parameter group including a second distance that is an effective distance between the source antenna and the probe, a current magnitude distribution of the source antenna and a current phase distribution of the source antenna, based on the first parameter group;
calculating the magnitude pattern at the first distance based on the second parameter group; and
determining the phase pattern at the first distance when the magnitude pattern at the calculated first distance matches with the magnitude pattern at the first distance included in the first parameter group by the comparison therebetween.

2. The method of claim 1, further comprising: if it is determined that the magnitude pattern at the calculated first distance does not match with the magnitude pattern at the first distance included in the first parameter group by the comparison therebetween, re-assuming the second parameter group.

3. The method of claim 2, wherein the calculating of the magnitude pattern at the first distance based on the second parameter group is calculated by the following Equation.
$${E}_{R 1} ( α , β ) = \int {\int }_{s}^{ } f ( x , y ) {e}^{- i \frac{2 π}{λ} p} d s$$
where E represents the near-field or the Fresnel field, R1 represent the distance from the antenna to the probe, α represents the vertical angle from the y-z plane, β represents the vertical angle from the x-z plane, S represents an area of the aperture of the antenna, f(x,y) represents the current magnitude distribution and the current phase distribution value of the antenna, and ρ represents the distance from the point spaced by the predetermined distance from the center on the aperture of the antenna to the probe.

4. The method of claim 2, wherein the calculating of the magnitude pattern at the first distance based on the second parameter group is calculated by the following Equation.
$${E}_{R 1} ( α , β ) = \int {\int }_{s}^{ } f ( x , y ) \frac{( 1 + i \frac{2 π}{λ} p )}{{p}^{3}} {e}^{- i \frac{2 π}{λ} p} d s$$
where E represents the near-field or the Fresnel field, R1 represent the distance from the antenna to the probe, α represents the vertical angle from the y-z plane, β represents the vertical angle from the x-z plane, S represents an area of the aperture of the antenna, f(x,y) represents the current magnitude distribution and the current phase distribution value of the antenna, and ρ represents the distance from the point spaced by the predetermined distance from the center on the aperture of the antenna to the probe.
